(19) United States
(12) Patent Application Publication
(10) Pub. No.: US 2018/0108549 A1
(43) Pub. Date: Apr. 19, 2018

(54) SUBSTRATE PROCESSING APPARATUS

(71) Applicants: BOE TECHNOLOGY GROUP CO., LTD., Beijing (CN); HEFEI XINSHENG OPTOELECTRONICS TECHNOLOGY CO., LTD, Anhui (CN)

(72) Inventors: Xiaoning LIU, Beijing (CN); Shikai WANG, Beijing (CN); Dongseob KIM, Beijing (CN); Jun GENG, Beijing (CN); Zhen HU, Beijign (CN); Xuanqi LIANG, Beijing (CN); Feng ZHANG, Beijing (CN); Tengfei HUANG, Beijing (CN); Yang PAN, Beijing (CN); Zhongren JIANG, Beijing (CN)

(21) Appl. No.: 15/554,823

(22) PCT Filed: Feb. 7, 2017
(86) PCT No.: PCT/CN2017/073046

§ 371 Date: Aug. 31, 2017

(30) Foreign Application Priority Data
May 9, 2016 (CN) 201620409839.5

(51) Int. Cl. H01L 21/67; H01L 21/677; H01J 37/32

(52) U.S. Cl. CPC H01L 21/67173; H01L 21/67051; H01L 21/6708; H01L 21/32134; H01L 21/67207; H01J 37/32009; H01J 37/32853; H01L 21/67742

(57) ABSTRACT

The disclosure provides a substrate processing apparatus. The substrate processing apparatus includes: an etching region and one or more aerosol absorption devices arranged outside a substrate inlet of the etching region. The aerosol absorption device includes one or more spraying pipes. The aerosol absorption device is capable of absorbing the aerosol of the etching solution from the etching region, thereby reducing the damage of the aerosol to the substrate processing components.

### RELATED APPLICATIONS

The present application is the U.S. national phase entry of the international application PCT/CN2017/073046, with an international filing date of Feb. 7, 2017, which claims the benefit of Chinese Patent Application No. 201620409839.5, filed on May 9, 2016, the entire disclosures of which are incorporated herein by reference.

### TECHNICAL FIELD

The present application relates to the technical field of substrate processing, and more particularly to a substrate processing apparatus including an aerosol absorption device.

### BACKGROUND

As the TFT-LCD (thin film transistor—liquid crystal display) technology of the 1990s matures, the liquid crystal display panel has been developed rapidly due to its overall performance advantages such as brightness, contrast, power consumption, life time, size and weight. In order to ensure the product's pass rate, the uniformity of the process is facing greater challenges. The process includes wet etching.

In wet etching, a portion of the metal layer on the glass substrate not covered with the photoresist is etched by the etchant to form a desired metal pattern. The etchant used for wet etching differs depending on the metal to be etched. For example, an etching solution for ITO (indium tin oxide) mainly includes nitric acid and sulfuric acid, an etching solution for Al (aluminum) metal mainly includes nitric acid, phosphoric acid and acetic acid, and an etching solution for Cu (copper) metal mainly includes acidic solution of hydrogen peroxide.

### SUMMARY

The present application proposes a substrate processing apparatus which can process the aerosol to reduce the influence of aerosol of the etching solution on the components outside the etching region.

According to an aspect, a substrate processing apparatus is provided. The substrate processing apparatus includes: an etching region and one or more aerosol absorption devices arranged outside a substrate inlet of the etching region. The aerosol absorption device includes one or more spraying pipes. The aerosol absorption device is used to absorb the aerosol diffused from the etching region, reducing the influence of the aerosol on the components outside the etching region.

In some embodiments, the spray pipe is arranged to spray absorbent liquid for contacting aerosol.

In some embodiments, the aerosol absorption device further includes a liquid supply pipe, a liquid discharge component and a plurality of nozzles arranged on each spray pipe.

In some embodiments, an interval for the plurality of nozzles arranged on each spray pipe is in a range of 10-50 mm.

In some embodiments, an exit direction of the nozzle is adjustable in a range of 15 to 45 degrees downward with respect to the horizontal plane.

In some embodiments, the aerosol absorption device further includes an inclined groove with an inclined ramp. The absorbent liquid is sprayed and reaches the liquid discharge component through the inclined ramp. The inclined groove can provide a stable contact area for the absorbent liquid and the aerosol, and reduce the spill of the absorbent liquid.

In some embodiments, an opening of the inclined groove faces the substrate inlet of the etching region. The liquid curtain of the absorbent liquid is directly guided to the substrate inlet of the etching region to increase the absorption efficiency.

In some embodiments, the inclined ramp is formed with a flat ramp or a wavy ramp. The wavy ramp can further increase the contact area.

In some embodiments, the substrate processing apparatus further includes a conveying device for conveying a substrate to be processed. The aerosol absorption device is arranged below the conveying device.

In some embodiments, the substrate processing apparatus further includes an atmospheric pressure plasma (APP) surface processing region. The aerosol absorption device is further positioned at a buffering region connecting the atmospheric pressure plasma surface processing region and the etching region.

In some embodiments, the substrate processing apparatus further includes an exhaust hood disposed above the conveying device and above the aerosol absorption device. The exhaust hood can cooperate with the aerosol absorption device to achieve a desired blocking effect.

In some embodiments, the absorbent liquid is water, alcohol liquid or alkaline solution. Different kinds of absorbent liquid should be applied for corresponding kinds of etching gas aerosol.

In some embodiments, the liquid supply pipe is connected to a plurality of liquid supply sources via a valve. The plurality of liquid supply sources respectively accommodate different types of absorbent liquid.

In some embodiments, the substrate processing apparatus further includes a cleaning region. The liquid discharge component is connected to a pipeline in the cleaning region via a valve. In this way, the recycling utilization of the absorbent liquid can be achieved.

In some embodiments, the substrate processing apparatus further includes a plurality of gas knives arranged at an outlet of the atmospheric pressure plasma surface processing region. The plurality of gas knives can form an air curtain for blocking. The air curtain in combination with the aerosol absorption device can further improve the blocking effect, protecting the APP electrode as far as possible.

In some embodiments, the plurality of gas knives supply clean dry air (CDA) with an adjustable pressure.

In some embodiments, an exhaust device is arranged at a bottom of the buffering region. The aerosol absorption devices are located between the exhaust device and the substrate inlet of the etching region.

The substrate processing apparatus according to the embodiment of the present application is capable of absorbing the aerosol of the etching solution flowing to the buffering region and further blocking the aerosol with the air curtain. On the one hand, the defect of broken line caused by crystallization of the aerosol at the outlet of the buffering region can be reduced. On the other hand, corrosion of the aerosol to the APP electrode can be prevented. Furthermore, in particular for copper etching, the copper oxidation caused by the interaction of the aerosol and APP can be avoided, thereby avoiding the defect of metal residue.

### BRIEF DESCRIPTION OF THE DRAWINGS

The accompanying drawings are included to provide a further understanding of the embodiments. The accompanying drawings are incorporated in and constitute a part of the specification. The drawings illustrate the embodiments and explain the principles of the present application in combination with the description. Many desirable advantages of other embodiments and embodiments will be readily appreciated by reference to the following detailed description. The elements of the drawings are not necessarily in proportion to each other. The same reference numerals refer to like components.

FIG. 1 shows a typical structural schematic diagram of a current wet etching apparatus;

FIG. 2 shows a structural schematic diagram of a substrate processing apparatus according to an embodiment of the present application;

FIG. 3 shows a structural schematic diagram of a substrate processing apparatus according to another embodiment of the present application;

FIG. 4 shows a structural schematic diagram of an aerosol absorption device according to an embodiment of the present application; and

FIG. 5 shows a structural schematic diagram of an aerosol absorption device according to another embodiment of the present application.

### DETAILED DESCRIPTION OF THE INVENTION

In the following detailed description, reference is made to the accompanying drawings, which form a part of the detailed description and are shown by way of illustrative and specific embodiments of the present application. In this regard, directional terms such as “top”, “bottom”, “left”, “right”, “upper”, “lower” and the like are used for reference to the orientation of the illustrated drawings. Since the components of the embodiments may be positioned in several different orientations, directional terms are used for illustrative purposes and directional terms are not limitations. It is to be understood that other embodiments may be utilized or logical changes may be made without departing from the scope of the present application. Accordingly, the following detailed description is not to be taken in a limiting sense, and the scope of the present application is defined by the appended claims.

It should be understood that the features of the various exemplary embodiments described herein can be combined with each other unless otherwise indicated.

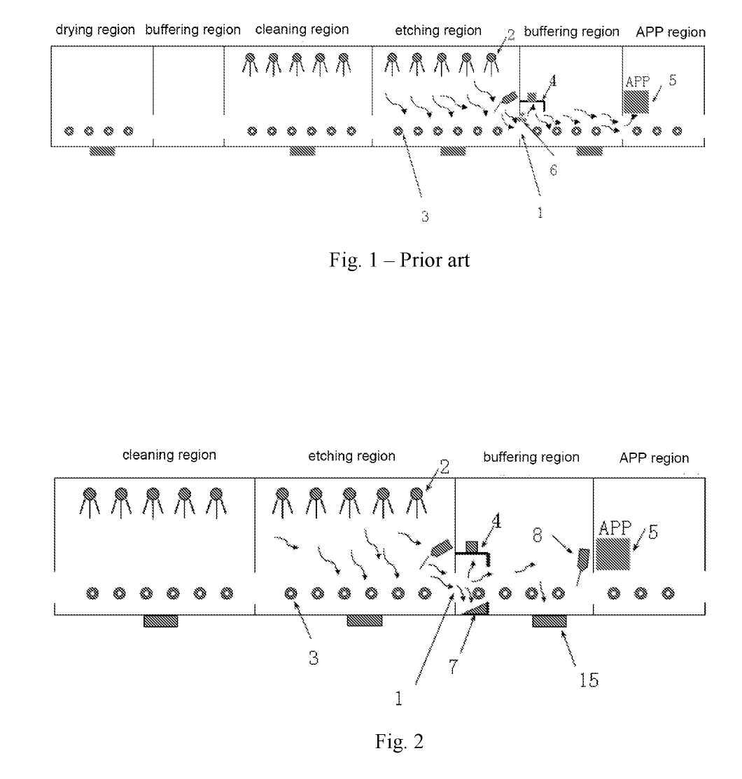

Referring to FIG. 1, FIG. 1 is a typical structural schematic diagram of a current wet etching apparatus. The apparatus includes an APP (atmospheric pressure plasma) region (for ionizing atmospheric pressure plasma to obtain reactive ions such as ionized oxygen, and removing organic matter before etching), a first buffering region, an etching region, a cleaning region, a second buffering region and a drying region (from right to left in the drawing). The etching apparatus drives the substrate mainly by the roller 3. A certain number of pipes 2 are distributed in the etching region and cleaning region, the liquid can be sprayed with some nozzles on the pipes.

Due to the existence of volatile acid in the etching liquid, the volatile acid gas (or aerosol) reaches the APP region from the buffering region, and etches the APP electrode 5, reducing the life time of the APP electrode 5 and increasing the risk of failure. In the wet etching process for the copper metal, the acid gas condenses into crystalline particles 6 at the outlet of the buffering region, which increases the risk of broken line failure. Moreover, due to the interaction of the acid gas and APP, the copper metal is oxidized and cannot be etched, resulting in the defect of metal residue.

In order to reduce the acid gas flowing into the buffer region, the existing etching apparatus includes a cover 4 mounted on the front end of the buffering region. The cover has an exhaust pipe for discharging the acid gas, and it is also required that the exhaust (or suction) pressure in the etching region is greater than the exhaust pressure in the buffering region. However, in actual use, the exhaust pressure tends to fluctuate, and the exhaust pressure of the buffering unit cannot be controlled precisely. If the exhaust pressure is too large, it is apt to absorb the acid gas from the etching region. If the exhaust pressure is too small, the acid gas flowing from the etching region cannot be discharged in time. Therefore, it is desirable to provide a better treatment device for acid gas (or aerosol).

FIG. 2 shows a substrate processing apparatus according to an embodiment of the present application. The apparatus can be used for wet etching of substrates such as glass substrates. In this embodiment, the substrate processing apparatus is provided with an atmospheric pressure plasma surface processing region (APP surface processing region, or APP region), a buffering region, an etching region and a cleaning region connected in turn. It is to be understood that the substrate processing apparatus can also be provided with other processing regions such as a drying region. A conveying device 3 for conveying a substrate (not shown in the figure) can be arranged in each region.

The buffering region is used to connect two adjacent regions (such as the atmospheric pressure plasma surface processing region and the etching region), providing buffering function in the pipeline operation. The atmospheric pressure plasma surface processing region (referred to as APP surface processing region) is provided with APP electrodes, for providing reactive ions before etching to remove the organic matter on the substrate. Nozzles 2 are provided in the etching region for spraying an etching solution on the substrate. The curved arrows in FIG. 2 show the volatile acid mist or aerosol produced by the etching solution during spraying, which is apt to enter the buffering region from the substrate inlet 1 of the etching region and enter the adjacent APP surface processing region.

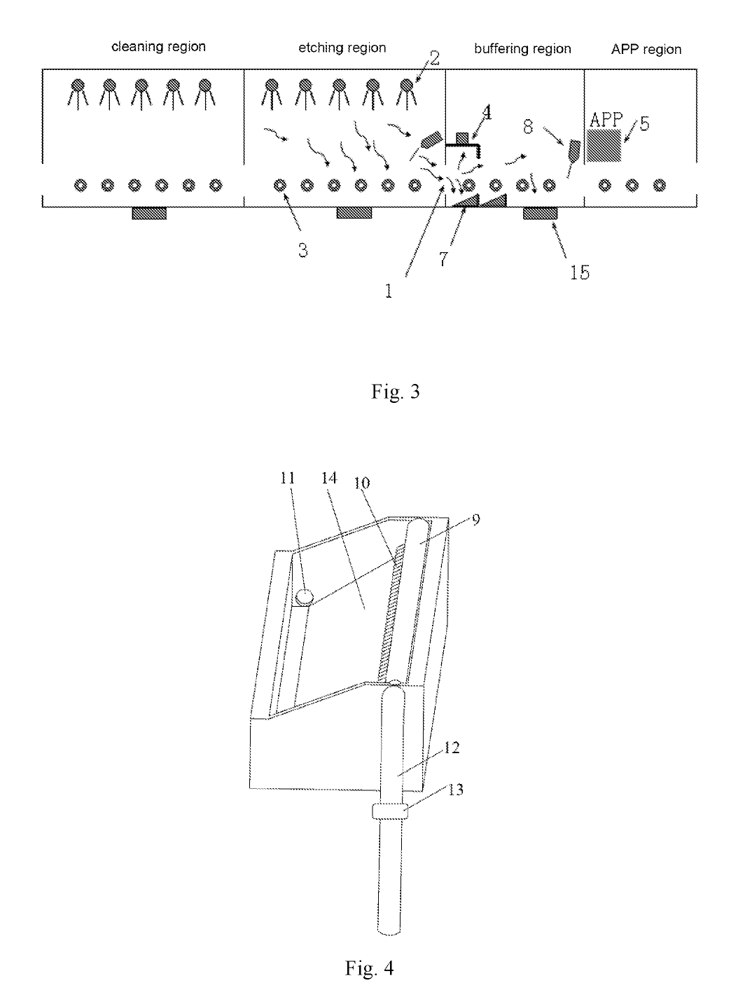

Therefore, in the embodiment of the present application, one or more aerosol absorption devices 7 are arranged outside the substrate inlet of the etching region. The aerosol absorption device 7 includes one or more spraying pipes. The spraying pipe is used for spraying absorbent liquid for contacting aerosol and making the absorbent liquid into contact with the aerosol escaping from the substrate inlet 1 of the etching region, thereby realizing the absorption or blocking of the aerosol. In particular, the aerosol absorption device 7 is arranged in the buffering region between the etching region and the APP surface processing region, and near the substrate outlet of the etching region. In some embodiments, the aerosol absorption device 7 is arranged below the conveying device 3 to improve the absorbent effect for the aerosol. Optionally, an exhaust hood 4 is disposed above the conveying device 3 and above the aerosol absorption device 7. The exhaust hood can cooperate with the aerosol absorption device to achieve a desired absorbent effect for the aerosol. Although only one aerosol absorption device 7 is depicted in FIG. 2, it will be appreciated that the number of the aerosol absorption device 7 can be multiple, and the aerosol absorption devices 7 can be uniformly arranged in the buffering region (for example, FIG. 3 shows an exemplary arrangement provided with two aerosol absorption devices 7). Furthermore, the aerosol absorption device 7 is not limited to the size shown in the drawings, the size can be made larger than that shown in the drawings.

In addition, in some embodiments, a gas curtain 8 close to the substrate inlet of the APP surface processing region is further provided in the buffering region. The air curtain 8 is used for further blocking the aerosol escaping into the buffering region, preventing the aerosol from entering the APP surface processing region. The air curtain 8 is formed by an air knife, and the air knife supplies CDA (clean dry air) with an adjustable pressure. The combination of the air curtain 8, the aerosol absorption device 7 and the exhaust hood 4 can realize a desired blocking effect for the aerosol.

On the one hand, with the substrate processing apparatus according to the embodiment of the present application, the defect of broken line caused by crystallization of the aerosol at the outlet of the buffering region can be reduced. On the other hand, corrosion of the aerosol to the APP electrode can be prevented. Furthermore, in particular for copper etching, the copper oxidation caused by the interaction of the aerosol and APP can be avoided, thereby avoiding the defect of metal residue.

FIG. 4 shows a specific configuration of the aerosol absorption device 7. In an embodiment of the present application, the aerosol absorption device 7 includes a liquid supply pipe 12, a liquid discharge component 11 and one or more nozzles 10 arranged on each spray pipe. The liquid supply pipe 12 is optionally provided with a valve 13 to regulate the flow and the flow rate of the absorbent liquid. The absorbent liquid is sprayed via one or more nozzles 10, and the absorbent liquid is then in contact with the aerosol to absorb the aerosol. The absorbent liquid is recycled by the liquid discharge component 11. In some embodiments, one or more nozzles 10 are disposed on the spray pipe 9, and spray the absorbent liquid obliquely with respect to the horizontal plane. The interval between the plurality of nozzles 10 disposed on the same spray pipe can be in the range of 10-50 mm. The exit angle of the nozzle 10 is optionally adjustable, and can be in a range of 15 to 45 degrees downward with respect to the horizontal plane. The adjustment can be achieved, for example, by rotating the spray pipe.

In a specific embodiment, the aerosol absorption device further includes an inclined groove with an inclined ramp 14. The spray pipe 9 is formed at the top of the inclined ramp 14. The absorbent liquid sprayed by the nozzles 10 reaches the liquid discharge component 11 through the inclined ramp 14. The liquid discharge component 11 is optionally provided at the base of the inclined ramp. The inclined ramp increases the area and time of contact between the absorbent liquid and the aerosol. It should be appreciated that the inclined ramp 14 is not limited to the shape shown in the drawing. The inclined ramp 14 can also have a wavy cross-sectional shape or other shapes increasing the contact area. In addition, the inclination angle and the area of the inclined ramp are not limited to those shown in the drawing, and can be arranged as necessary. Furthermore, the opening of the inclined groove is optionally oriented toward the substrate inlet of the etching region (i.e., the substrate outlet of the buffering region), so that the aerosol can be absorbed more effectively by the absorbent liquid in time.

For different types of etching solution, the absorbent solution may be different. For example, for a copper etching solution of hydrogen peroxide, the absorbent liquid can be water or alcohol solution apt to absorb hydrogen peroxide. For an ITO or Al etching solution, the absorbent liquid can be alkaline solution, such as sodium hydroxide solution.

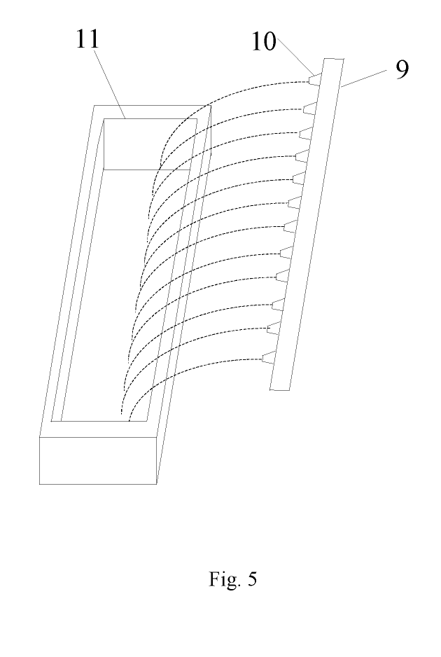

Of course, the inclined ramp is not essential in the aerosol absorption device 7. In another embodiment of the present application, as shown in FIG. 5, an air curtain can be formed in the air only by spraying (via a plurality of nozzles 10) of the spray pipe 9, thereby achieving a blocking effect for the aerosol. Furthermore, the liquid discharge component 11 is arranged on the bottom to discharge the sprayed liquid.

In an optional embodiment, the liquid discharge component 11 can be connected to a cleaning pipeline in the cleaning region of the substrate processing apparatus, and the discharged absorbent liquid (e.g., water) can be used to clean the substrate. This arrangement is more economical.

In some embodiments, an exhaust device 15 is arranged at the bottom of the buffering region. The aerosol absorption devices 7 are located between the exhaust device 15 and the substrate inlet 1 of the etching region. This arrangement can attract more aerosol for contacting the aerosol absorption devices 7, thereby further improving the absorbent effect for the aerosol.

In other embodiments, the liquid supply pipe of the aerosol absorption device 7 can be connected to a plurality of liquid supply sources. The plurality of liquid supply sources respectively accommodate different types of absorbent liquid for corresponding aerosol of etching liquid. Therefore, the type of the absorbent liquid supplied to the liquid supply pipe 9 can be adjusted based on the currently used etching solution, improving the adaptability of the substrate processing apparatus.

The above embodiments are only used for explanations rather than limitations to the present invention, the ordinary skilled person in the related technical field, in the case of not departing from the spirit and scope of the present invention, may also make various modifications and variations, therefore, all the equivalent solutions also belong to the scope of the present invention, the patent protection scope of the present invention should be defined by the claims.

In the description of the present application, it is to be understood that the azimuth or positional relationship indicated by the terms “up”, “down”, “inside”, “outside”, etc. is based on the azimuth or positional relationship shown in the drawings for the description of the present application and the simplified description, rather than indicating or implied that the device or element is intended to have a particular orientation, is constructed and operated in a particular orientation and is therefore not to be construed as limiting the present application. The phrase “comprising” does not exclude the presence of elements or steps not listed in the claims. The phrase ‘a’ or ‘an’ in front of the element does not exclude the presence of multiple elements. The mere fact that certain measures are recited in mutually different dependent claims does not indicate that the combination of these measures cannot be used for improvement. Any reference signs in the claims should not be construed as limiting the scope.

1. A substrate processing apparatus, comprising: an etching region and one or more aerosol absorption devices arranged outside a substrate inlet of the etching region, wherein the aerosol absorption device comprises one or more spraying pipes.

2. The apparatus according to claim 1, wherein the spray pipe is arranged to spray absorbent liquid for contacting aerosol.

3. The apparatus according to claim 2, wherein the aerosol absorption device further comprises a liquid supply pipe, a liquid discharge component and a plurality of nozzles arranged on each spray pipe.

4. The apparatus according to claim 3, wherein an interval for the plurality of nozzles arranged on each spray pipe is in a range of 10-50 mm.

5. The apparatus according to claim 3, wherein an exit direction of the nozzle is adjustable in a range of 15 to 45 degrees downward with respect to the horizontal plane.

6. The apparatus according to claim 3, wherein the aerosol absorption device further comprises an inclined groove with an inclined ramp, the absorbent liquid is sprayed and reaches the liquid discharge component through the inclined ramp.

7. The apparatus according to claim 6, wherein an opening of the inclined groove faces the substrate inlet of the etching region.

8. The apparatus according to claim 6, wherein the inclined ramp is formed with a flat ramp or a wavy ramp.

9. The apparatus according to claim 1, further comprising a conveying device for conveying a substrate to be processed; the aerosol absorption device is arranged below the conveying device.

10. The apparatus according to claim 1, further comprising an atmospheric pressure plasma surface processing region, the aerosol absorption device is further positioned at a buffering region connecting the atmospheric pressure plasma surface processing region and the etching region.

11. The apparatus according to claim 9, further comprising an exhaust hood disposed above the conveying device and above the aerosol absorption device.

12. The apparatus according to claim 2, wherein the absorbent liquid is water, alcohol liquid or alkaline solution.

13. The apparatus according to claim 4, wherein the liquid supply pipe is connected to a plurality of liquid supply sources via a valve; the plurality of liquid supply sources respectively accommodate different types of absorbent liquid.

14. The apparatus according to claim 4, further comprising a cleaning region, the liquid discharge component is connected to a pipeline in the cleaning region via a valve.

15. The apparatus according to claim 10, further comprising a plurality of gas knives arranged at an outlet of the atmospheric pressure plasma surface processing region.

16. The apparatus according to claim 15, wherein the plurality of gas knives supply clean dry air with an adjustable pressure.

17. The apparatus according to claim 10, wherein an exhaust device is arranged at a bottom of the buffering region; the aerosol absorption devices are located between the exhaust device and the substrate inlet of the etching region.

18. The apparatus according to claim 2, further comprising an atmospheric pressure plasma surface processing region, the aerosol absorption device is further positioned at a buffering region connecting the atmospheric pressure plasma surface processing region and the etching region.

19. The apparatus according to claim 3, further comprising an atmospheric pressure plasma surface processing region, the aerosol absorption device is further positioned at a buffering region connecting the atmospheric pressure plasma surface processing region and the etching region.

20. The apparatus according to claim 6, further comprising an atmospheric pressure plasma surface processing region, the aerosol absorption device is further positioned at a buffering region connecting the atmospheric pressure plasma surface processing region and the etching region.
